(19) United States
(12) Patent Application Publication
(10) Pub. No.: US 2010/0288354 A1
(43) Pub. Date: Nov. 18, 2010

(54) CADMIUM STANNATE TCO STRUCTURE WITH DIFFUSION BARRIER LAYER AND SEPARATION LAYER

(75) Inventors: Scott Mills, Perrysburg, OH (US); Dale Roberts, Temperance, MI (US); Zhibo Zhao, Novi, MI (US); Yu Yang, Perrysburg, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/782,527

(22) Filed: May 18, 2010

Related U.S. Application Data
(60) Provisional application No. 61/179,303, filed on May 18, 2009.

(51) Int. Cl. H01L 31/0224; H01L 31/18; H01L 29/43; H01L 21/283

(52) U.S. Cl. 136/256; 438/98; 257/750; 438/609; 257/E31.126; 257/E29.139; 257/E21.159

(57) ABSTRACT

A photovoltaic device can include a transparent conductive oxide layer adjacent to a substrate and one or more barrier layers, which can include a silicon oxide or a silicon nitride.

### CLAIM FOR PRIORITY

This application claims priority under 35 U.S.C. §119(e) to U.S. Provisional Patent Application Ser. No. 61/179,303 filed on May 18, 2009, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices can also contain one or more transparent conductive oxide layers, which are also often conductors of electrical charge.

### DESCRIPTION OF DRAWINGS

FIG. 1 is a schematic of a photovoltaic device having multiple layers.

FIG. 2 is a schematic of a photovoltaic device having multiple layers.

FIG. 3 is a schematic of a photovoltaic device having multiple layers.

FIG. 4 is a schematic of a photovoltaic device having multiple layers.

FIG. 5 is a schematic of a photovoltaic device having multiple layers.

FIG. 6 is a schematic of a photovoltaic device having multiple layers.

### DETAILED DESCRIPTION

Photovoltaic devices can include multiple layers created on a substrate (or superstrate).

For example, a photovoltaic device can include a barrier layer, a transparent conductive oxide

(TCO) layer, a buffer layer, and a semiconductor layer formed in a stack on a substrate. Each layer may in turn include more than one layer or film. For example, the semiconductor layer can include a first film including a semiconductor window layer, such as a cadmium sulfide layer, formed on the buffer layer and a second film including a semiconductor absorber layer, such as a cadmium telluride layer formed on the semiconductor window layer. Additionally, each layer can cover all or a portion of the device and/or all or a portion of the layer or substrate underlying the layer. For example, a “layer” can include any amount of any material that contacts all or a portion of a surface.

Photovoltaic devices can be formed on optically transparent substrates, such as glass. Because glass is not conductive, a TCO layer is typically deposited between the substrate and the semiconductor bi-layer. Cadmium stannate functions well in this capacity, as it exhibits high optical transmission and low electrical sheet resistance. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability, and good adhesive properties. Therefore the TCO can be part of a three-layer stack, which may include, for example, a silicon dioxide barrier layer, a cadmium stannate TCO layer, and a buffer layer (e.g., a tin (IV) oxide). The buffer layer can include various suitable materials, including tin oxide, zinc tin oxide, zinc oxide, and zinc magnesium oxide.

A variety of barrier materials may be included in the TCO stack, including a silicon oxide and/or a silicon nitride. The TCO stack can include a silicon nitride, silicon oxide, aluminum-doped silicon oxide, boron-doped silicon nitride, phosphorus-doped silicon nitride, silicon oxide-nitride, or any combination or alloy thereof. The dopant can be less than 25%, less than 20%, less than 15%, less than 10%, less than 5% or less than 2%. The TCO stack may include multiple barrier materials. For example, the TCO stack can include a barrier bi-layer consisting essentially of a silicon oxide deposited over a silicon nitride (or an aluminum-doped silicon nitride). The barrier bi-layer can be optimized using optical modeling to achieve both color suppression and reduced reflection loss, though in practice a thicker bi-layer may be needed to block sodium more effectively. A tin oxide can be introduced as a control layer to enable proper cadmium stannate transformation in a nitrogen gas or low vacuum annealing process.

In one aspect, a photovoltaic device can include a transparent conductive oxide layer adjacent to a substrate. The transparent conductive oxide layer can include a cadmium stannate layer. The photovoltaic device can include one or more barrier layers positioned between the substrate and the transparent conductive oxide layer. Each of the one or more barrier layers can include a silicon oxide or a silicon nitride. The photovoltaic device can include a tin oxide layer adjacent to the transparent conductive oxide layer. The photovoltaic device can include a buffer layer adjacent to the tin oxide layer. The photovoltaic device can include a semiconductor bi-layer adjacent to the buffer layer. The semiconductor bi-layer can include a semiconductor absorber layer adjacent to a semiconductor window layer.

The buffer layer can include a tin oxide layer. The buffer layer can include a tin oxide, zinc tin oxide, zinc oxide, or zinc magnesium oxide. The transparent conductive oxide layer can have a thickness of about 100 nm to about 1000 nm. The one or more barrier layers can include a silicon nitride. The one or more barrier layers can include a silicon oxide. The one or more barrier layers can include a silicon oxide adjacent to a silicon nitride. The one or more barrier layers can include an aluminum-doped silicon oxide adjacent to an aluminum-doped silicon nitride. The aluminum content of the aluminum-doped silicon nitride or silicon oxide can be less than 20%, less than 18%, less than or equal to 15% (i.e., the Si/Al ratio is 85/15), or less than or equal to 10%. The one or more barrier layers can include a first silicon oxide adjacent to a silicon nitride. The silicon nitride can be adjacent to a second silicon oxide. The one or more barrier layers can include a first aluminum-doped silicon oxide adjacent to an aluminum-doped silicon nitride. The aluminum-doped silicon nitride can be adjacent to a second aluminum-doped silicon oxide. The tin oxide layer can have a thickness of about 10 nm to about 100 nm. The buffer layer can have a thickness of about 10 nm to about 100 nm. The semiconductor absorber layer can include a cadmium telluride layer. The semiconductor window layer can include a cadmium sulfide layer. The substrate can include a glass. The glass can include a soda-lime glass. The device can include a back contact adjacent to the semiconductor bi-layer, and a back support adjacent to the back contact.

In one aspect, a method for manufacturing a photovoltaic device can include depositing a transparent conductive oxide layer adjacent to one or more barrier layers. The transparent conductive oxide layer can include a cadmium stannate layer. Each of the one or more barrier layers can include a silicon oxide or a silicon nitride. The method can include depositing a tin oxide layer adjacent to the transparent conductive oxide layer. The method can include depositing a buffer layer adjacent to the tin oxide layer. The one or more barrier layers and the deposited transparent conductive oxide layer, tin oxide layer, and buffer layer can form a transparent conductive oxide stack. The method can include annealing the transparent conductive oxide stack. The method can include depositing a semiconductor window layer adjacent to the transparent conductive oxide stack. The method can include depositing a semiconductor absorber layer adjacent to the semiconductor window layer.

The buffer layer can include a tin oxide layer. The buffer layer can include a tin oxide, zinc tin oxide, zinc oxide, or zinc magnesium oxide. The method can include depositing the transparent conductive oxide stack adjacent to a substrate. The method can include depositing the one or more barrier layers adjacent to a substrate using a chemical vapor deposition process. The step of depositing the one or more barrier layers can include depositing a silicon nitride adjacent to the substrate. The step of depositing the one or more barrier layers can include depositing a silicon oxide adjacent to the substrate. The step of depositing the one or more barrier layers can include depositing a silicon nitride adjacent to the substrate. The step of depositing the one or more barrier layers can include depositing a silicon oxide adjacent to the silicon nitride. The step of depositing the one or more barrier layers can include depositing an aluminum-doped silicon nitride adjacent to the substrate. The step of depositing the one or more barrier layers can include depositing an aluminum-doped silicon oxide adjacent to the aluminum-doped silicon nitride. The step of depositing the one or more barrier layers can include depositing a first silicon oxide adjacent to the substrate. The step of depositing the one or more barrier layers can include depositing a silicon nitride adjacent to the first silicon oxide. The step of depositing the one or more barrier layer can include depositing a second silicon oxide adjacent to the silicon nitride. The step of depositing the one or more barrier layers can include depositing a first aluminum-doped silicon oxide adjacent to the substrate. The step of depositing the one or more barrier layers can include depositing an aluminum-doped silicon nitride adjacent to the first aluminum-doped silicon oxide. The step of depositing the one or more barrier layers can include depositing a second aluminum-doped silicon oxide adjacent to the aluminum-doped silicon nitride.

The step of annealing the transparent conductive oxide stack can include heating the transparent conductive oxide stack in a furnace. The step of annealing the transparent conductive oxide stack can include annealing in a nitrogen-containing atmosphere. The substrate can include a glass. The glass can include a soda-lime glass. The step of depositing a transparent conductive oxide layer adjacent to one or more barrier layers can include sputtering a cadmium stannate layer onto the one or more barrier layers. The cadmium stannate layer can have a thickness of about 100 nm to about 1000 nm. The step of depositing a tin oxide layer adjacent to the transparent conductive oxide layer can include sputtering a tin oxide layer onto a cadmium stannate layer. The tin oxide layer can have a thickness of about 10 nm to about 100 nm. The step of depositing a buffer layer adjacent to the tin oxide layer layer can include sputtering a second tin oxide layer onto a first tin oxide layer. The tin oxide layer can have a thickness of about 10 nm to about 100 nm. The step of depositing a semiconductor window layer adjacent to the buffer layer can include depositing a cadmium sulfide layer. The step of depositing a semiconductor window layer adjacent to the buffer layer can include transporting a vapor. The step of depositing a semiconductor absorber layer adjacent to the semiconductor window layer can include depositing a cadmium telluride layer adjacent to a cadmium sulfide layer. The step of depositing a semiconductor absorber layer adjacent to the semiconductor window layer can include transporting a vapor. The method can include depositing a back contact adjacent to the semiconductor absorber layer. The method can include depositing a back support adjacent to the back contact.

In one aspect, a multi-layered substrate can include a transparent conductive oxide layer adjacent to a substrate. The transparent conductive oxide layer can include a cadmium stannate layer. The multi-layered substrate can include one or more barrier layers positioned between the substrate and the transparent conductive oxide layer. Each of the one or more barrier layers can include a silicon oxide or a silicon nitride. The multi-layered structure can include a tin oxide layer adjacent to the transparent conductive oxide layer. The multi-layered structure can include a buffer layer adjacent to the tin oxide layer.

The buffer layer can include a tin oxide layer. The buffer layer can include a tin oxide, zinc tin oxide, zinc oxide, or zinc magnesium oxide. The transparent conductive oxide layer can include a thickness of about 100 nm to about 1000 nm. The one or more barrier layers can include a silicon nitride. The one or more barrier layers can include a silicon oxide. The one or more barrier layers can include a silicon oxide layer adjacent to a silicon nitride layer. The one or more barrier layers can include an aluminum-doped silicon oxide layer adjacent to an aluminum-doped silicon nitride layer. The one or more barrier layers can include a first silicon oxide layer adjacent to a silicon nitride layer. The silicon nitride layer can be positioned adjacent to a second silicon oxide layer. The one or more barrier layers can include a first aluminum-doped silicon oxide layer adjacent to an aluminum-doped silicon nitride layer. The aluminum-doped silicon nitride layer can be positioned adjacent to a second aluminum-doped silicon oxide layer. The tin oxide layer can include a thickness of about 10 nm to about 100 nm. The buffer layer can include a thickness of about 10 nm to about 100 nm.

In one aspect, a method for manufacturing a multi-layered substrate can include depositing one or more barrier layers adjacent to a first substrate. The method can include depositing a transparent conductive oxide layer adjacent to the one or more barrier layers. The transparent conductive oxide layer can include a cadmium stannate layer. Each of the one or more barrier layers can include a silicon oxide or a silicon nitride. The method can include depositing a tin oxide layer adjacent to the transparent conductive oxide layer. The method can include depositing a buffer layer adjacent to the tin oxide layer. The first substrate, the deposited one or more barrier layers, transparent conductive oxide layer, tin oxide layer, and buffer layer can form a transparent conductive oxide stack. The method can include annealing the transparent conductive oxide stack.

The buffer layer can include a tin oxide layer. The buffer layer can include a tin oxide, zinc tin oxide, zinc oxide, and zinc magnesium oxide. Depositing the one or more barrier layers can include a chemical vapor deposition process. Depositing the one or more barrier layers can include depositing a silicon nitride layer. Depositing the one or more barrier layers can include depositing a silicon oxide layer. Depositing the one or more barrier layers can include depositing a silicon nitride layer. Depositing the one or more barrier layers can include depositing a silicon oxide layer adjacent to the silicon nitride layer. Depositing the one or more barrier layers can include depositing an aluminum-doped silicon nitride layer. Depositing the one or more barrier layers can include depositing an aluminum-doped silicon oxide layer adjacent to the aluminum-doped silicon nitride layer. Depositing the one or more barrier layers can include depositing a first silicon oxide layer. Depositing the one or more barrier layers can include depositing a silicon nitride layer adjacent to the first silicon oxide layer. Depositing the one or more barrier layers can include depositing a second silicon oxide layer adjacent to the silicon nitride layer. Depositing the one or more barrier layers can include depositing a first aluminum-doped silicon oxide layer. Depositing the one or more barrier layers can include depositing an aluminum-doped silicon nitride layer adjacent to the first aluminum-doped silicon oxide layer. Depositing the one or more barrier layers can include depositing a second aluminum-doped silicon oxide layer adjacent to the aluminum-doped silicon nitride layer. Annealing the transparent conductive oxide stack can include heating the transparent conductive oxide stack in a furnace. Annealing the transparent conductive oxide stack can include annealing in a nitrogen-containing atmosphere. The first substrate can include a glass. The glass can include a soda-lime glass. Depositing a transparent conductive oxide layer adjacent to the one or more barrier layers can include sputtering a cadmium stannate layer onto the one or more barrier layers. The cadmium stannate layer can have a thickness of about 100 nm to about 1000 nm. Depositing a tin oxide layer adjacent to the transparent conductive oxide layer can include sputtering a tin oxide layer onto a cadmium stannate layer. The tin oxide layer can have a thickness of about 10 nm to about 100 nm. Depositing a buffer layer adjacent to the tin oxide layer can include sputtering a second tin oxide layer onto a first tin oxide layer. The second tin oxide layer can have a thickness of about 10 nm to about 100 nm.

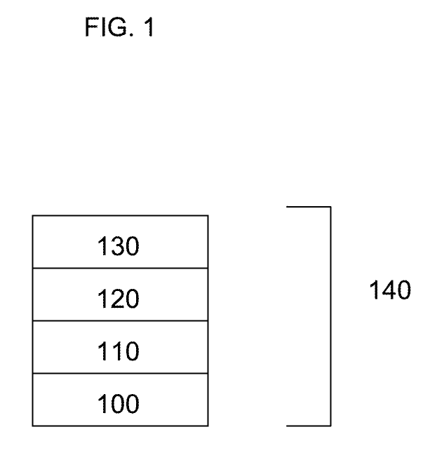

FIG. 1 shows a transparent conductive oxide stack 140 including a first barrier layer 100. First barrier layer 100 can include any suitable barrier material including a silicon oxide, silicon nitride, aluminum-doped silicon oxide, or aluminum-doped silicon nitride. For example, first barrier layer 100 can include a silicon dioxide or a silicon nitride (e.g., Si₃N₄ and compositions off stoichiometry by 10%). Transparent conductive oxide layer 110 can be deposited adjacent to first barrier layer 100. Transparent conductive oxide layer 110 can include cadmium stannate and can be of any suitable thickness. For example, transparent conductive oxide layer 110 can have a thickness of about 100 nm to about 1000 nm. Transparent conductive oxide layer 110 can be deposited using any known deposition technique, including sputtering.

The TCO stack can be manufactured using a variety of deposition techniques, including for example, low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000A.

A sputtering target can be manufactured by ingot metallurgy. A sputtering target can be manufactured from cadmium, tin, silicon, or alumium, or combinations or alloys thereof suitable to make the layer. For example, the target can be Si₈₅Al₁₅ The cadmium and tin can be present in the same target in stoichiometrically proper amounts. A sputtering target can be manufactured as a single piece in any suitable shape. A sputtering target can be a tube. A sputtering target can be manufactured by casting a metallic material into any suitable shape, such as a tube.

A sputtering target can be manufactured from more than one piece. A sputtering target can be manufactured from more than one piece of metal, for example, a piece of cadmium and a piece of tin. The cadmium and tin can be manufactured in any suitable shape, such as sleeves, and can be joined or connected in any suitable manner or configuration. For example, a piece of cadmium and a piece of tin can be welded together to form the sputtering target. One sleeve can be positioned within another sleeve.

A sputtering target can be manufactured by powder metallurgy. A sputtering target can be formed by consolidating metallic powder (e.g., cadmium or tin powder) to form the target. The metallic powder can be consolidated in any suitable process (e.g., pressing such as isostatic pressing) and in any suitable shape. The consolidating can occur at any suitable temperature. A sputtering target can be formed from metallic powder including more than one metal powder (e.g., cadmium and tin). More than one metallic powder can be present in stoichiometrically proper amounts.

A sputter target can be manufactured by positioning wire including target material adjacent to a base. For example wire including target material can be wrapped around a base tube. The wire can include multiple metals (e.g., cadmium and tin) present in stoichiometrically proper amounts. The base tube can be formed from a material that will not be sputtered. The wire can be pressed (e.g., by isostatic pressing).

A sputter target can be manufactured by spraying a target material onto a base. Metallic target material can be sprayed by any suitable spraying process, including thermal spraying and plasma spraying. The metallic target material can include multiple metals (e.g., cadmium and tin), present in stoichiometrically proper amounts. The base onto which the metallic target material is sprayed can be a tube.

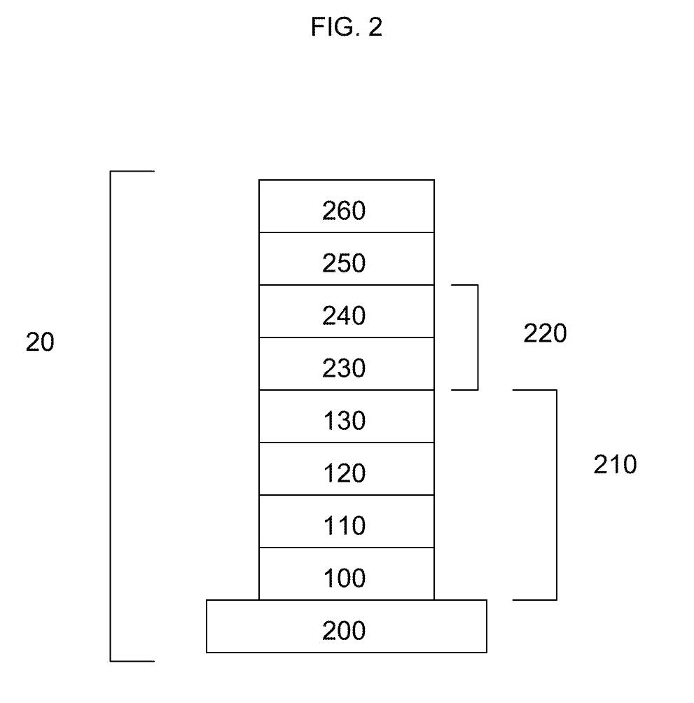

Referring again to FIG. 1, a control layer 120 can be deposited adjacent to transparent conductive oxide layer 110 to enable proper transformation of transparent conductive oxide layer 110 (e.g., cadmium stannate). Control layer 120 can be deposited using any known deposition technique, including sputtering. Control layer 120 can include a tin oxide and can be of any suitable thickness. For example, control layer 120 can have a thickness of about 10 nm to about 100 nm. A buffer layer 130 can be deposited adjacent to control layer 120 to facilitate proper deposition of semiconductor window layer 230 from FIG. 2. Buffer layer 130 can be deposited using any known deposition technique, including sputtering. Buffer layer 130 can include a tin(IV) oxide and can be of any suitable thickness. For example, buffer layer 130 can have a thickness of about 10 nm to about 100 nm.

Transparent conductive oxide stack 140 from FIG. 1 can be annealed to form annealed transparent conductive oxide stack 210 from FIG. 2. Transparent conductive oxide stack 140 can be annealed using any suitable annealing process. The annealing can occur in the presence of a gas selected to control an aspect of the annealing, for example nitrogen gas. Transparent conductive oxide stack 140 can be annealed under any suitable pressure, for example, under reduced pressure, in a low vacuum, or at about 0.01 Pa (10⁻⁴ Ton). Transparent conductive oxide stack 140 can be annealed at any suitable temperature or temperature range. For example, transparent conductive oxide stack 140 can be annealed at about 400° C. to about 800° C. Transparent conductive oxide stack 140 can be annealed at about 500° C. to about 700° C. Transparent conductive oxide stack 140 can be annealed for any suitable duration. Transparent conductive oxide stack 140 can be annealed for about 10 to about 25 minutes. Transparent conductive oxide stack 140 can be annealed for about 15 to about 20 minutes.

Annealed transparent conductive oxide stack 210 can be used to form photovoltaic device 20 from FIG. 2. Referring to FIG. 2, a semiconductor bi-layer 220 can be deposited adjacent to annealed transparent conductive oxide stack 210. Semiconductor bi-layer 220 can include a semiconductor window layer 230 and a semiconductor absorber layer 240. Semiconductor window layer 230 can be deposited adjacent to annealed transparent conductive oxide stack 210. Semiconductor window layer 230 can be deposited using any known deposition technique, including vapor transport deposition. Semiconductor absorber layer 240 can be deposited adjacent to semiconductor window layer 230. Semiconductor absorber layer 240 can be deposited using any known deposition technique, including vapor transport deposition. Semiconductor window layer 230 can include a cadmium sulfide layer. Semiconductor absorber layer 240 can include a cadmium telluride layer. A back contact 250 can be deposited adjacent to semiconductor bi-layer 210. Back contact 250 can be deposited adjacent to semiconductor absorber layer 240. A back support 260 can be deposited adjacent to back contact 250.

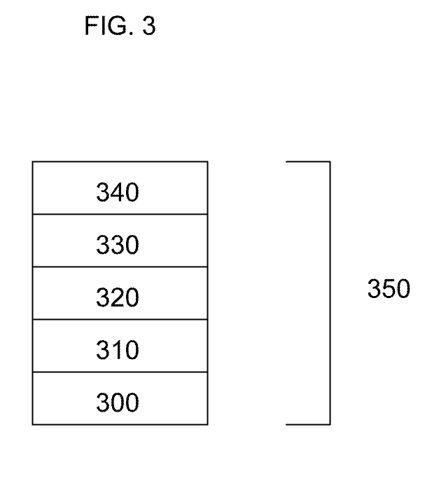

FIG. 3 shows an embodiment in which transparent conductive oxide stack 350 includes a first barrier layer 300 and a second barrier layer 310. Second barrier layer 310 can be deposited adjacent to first barrier layer 300. Second barrier layer 310 can be deposited using any known deposition technique, including sputtering. First barrier layer 300 can include any suitable barrier material, including a silicon nitride or an aluminum-doped silicon nitride. Second barrier layer 310 can include any suitable barrier material, including a silicon oxide or an aluminum-doped silicon oxide. Transparent conductive oxide stack 350 can include a silicon dioxide deposited over a silicon nitride. Transparent conductive oxide stack 350 can include an aluminum-doped silicon oxide deposited over an aluminum-doped silicon nitride. Deposition of aluminum-doped silicon oxide or silicon oxide over silicon nitride or aluminum-doped silicon nitride can prevent direct contact between the nitrogen and transparent conductive oxide layer 320, and thus ensure proper transformation of transparent conductive oxide layer 320 (e.g., cadmium stannate). First barrier layer 300 and second barrier layer 310 can be optimized using optical modeling to achieve both color suppression and reduced reflection loss.

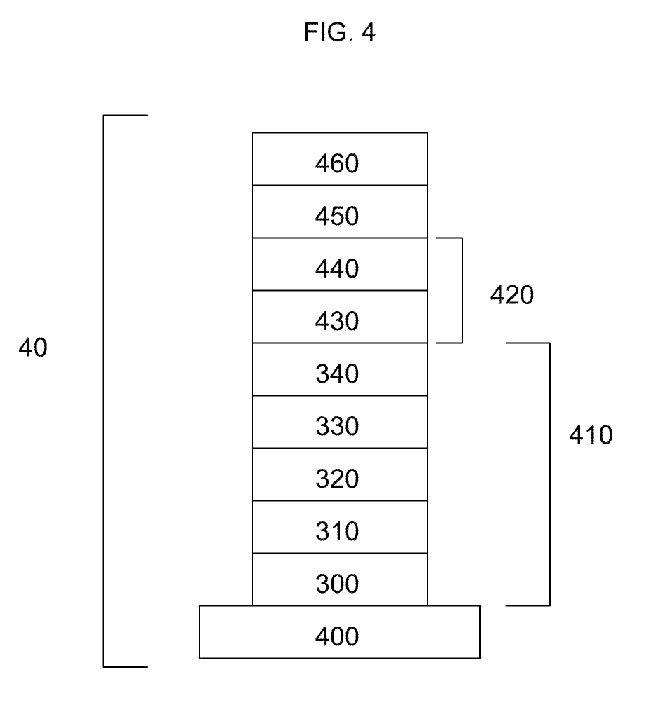

Transparent conductive oxide layer 320 can be deposited adjacent to second barrier layer 310. Transparent conductive oxide layer 320 can be deposited using any known deposition technique, including sputtering. Transparent conductive oxide layer 320 can be a cadmium stannate and can be of any suitable thickness. For example, transparent conductive oxide layer 320 can have a thickness of about 100 nm to about 1000 nm. A control layer 330 can be deposited adjacent to transparent conductive oxide layer 320 to enable proper transformation of transparent conductive oxide layer 320 (e.g., cadmium stannate). Control layer 330 can be deposited using any known deposition technique, including sputtering. Control layer 330 can include a tin oxide and can be of any suitable thickness. For example, control layer 330 can have a thickness of about 10 nm to about 100 nm. A buffer layer 340 can be deposited adjacent to control layer 330 to facilitate proper deposition of semiconductor window layer 430 from FIG. 4. Buffer layer 340 can be deposited using any known deposition technique, including sputtering. Buffer layer 340 can include a tin(IV) oxide and can be of any suitable thickness. For example, buffer layer 340 can have a thickness of about 10 nm to about 100 nm.

Transparent conductive oxide stack 350 from FIG. 3 can be annealed to form annealed transparent conductive oxide stack 410 from FIG. 4. Transparent conductive oxide stack 350 can be annealed using any suitable annealing process. The annealing can occur in the presence of a gas selected to control an aspect of the annealing, for example nitrogen gas. Transparent conductive oxide stack 350 can be annealed under any suitable pressure, for example, under reduced pressure, in a low vacuum, or at about 0.01 Pa (10⁻⁴ Ton). Transparent conductive oxide stack 350 can be annealed at any suitable temperature or temperature range. For example, transparent conductive oxide stack 350 can be annealed at about 400° C. to about 800° C. Transparent conductive oxide stack 350 can be annealed at about 500° C. to about 700° C. Transparent conductive oxide stack 350 can be annealed for any suitable duration. Transparent conductive oxide stack 350 can be annealed for about 10 to about 25 minutes. Transparent conductive oxide stack 350 can be annealed for about 15 to about 20 minutes.

Annealed transparent conductive oxide stack 410 can be used to form photovoltaic device 40 from FIG. 4. Referring to FIG. 4, a semiconductor bi-layer 420 can be deposited adjacent to annealed transparent conductive oxide stack 410. Semiconductor bi-layer 420 can include a semiconductor window layer 430 and a semiconductor absorber layer 440. Semiconductor window layer 430 can be deposited adjacent to annealed transparent conductive oxide stack 410. Semiconductor window layer 430 can be deposited using any known deposition technique, including vapor transport deposition. Semiconductor absorber layer 440 can be deposited adjacent to semiconductor window layer 430. Semiconductor absorber layer 440 can be deposited using any known deposition technique, including vapor transport deposition. Semiconductor window layer 430 can include a cadmium sulfide layer. Semiconductor absorber layer 440 can include a cadmium telluride layer. A back contact 450 can be deposited adjacent to semiconductor bi-layer 410. Back contact 450 can be deposited adjacent to semiconductor absorber layer 440. A back support 460 can be deposited adjacent to back contact 450.

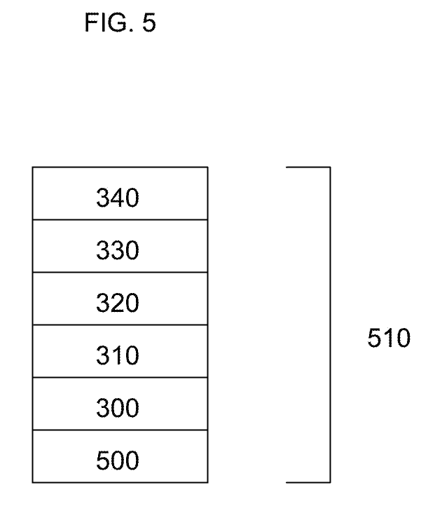

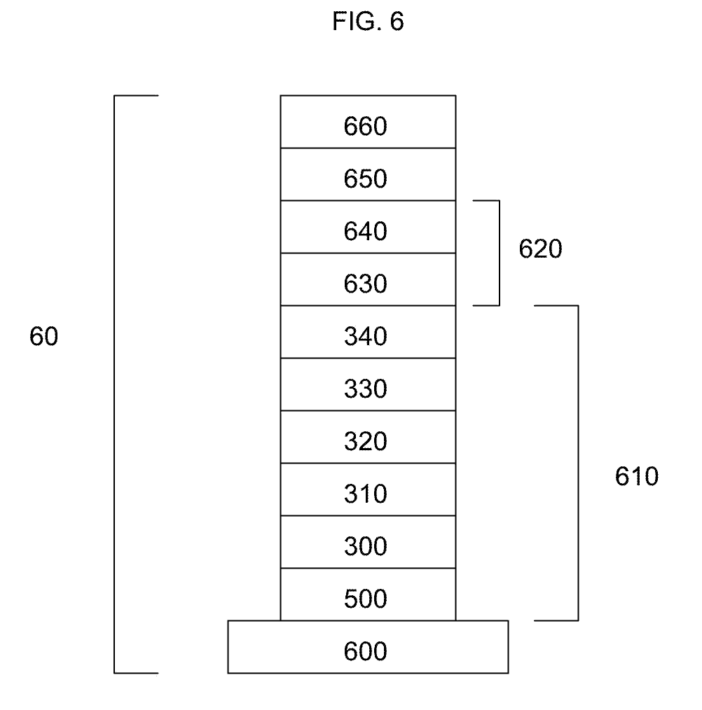

FIG. 5 shows an embodiment, in which first barrier layer 300 can be deposited adjacent to an additional barrier layer 500. First barrier layer 300 can be deposited using any known deposition technique, including sputtering. Second barrier layer 310 can be deposited onto first barrier layer 300. Second barrier layer 310 can be deposited using any known deposition technique, including sputtering. First barrier layer 300 can include a silicon nitride or an aluminum-doped silicon nitride. Second barrier layer 310 can include a silicon oxide or an aluminum-doped silicon oxide. Additional barrier layer 500 can include any suitable barrier material, including a silicon nitride, aluminum-doped silicon nitride, silicon oxide, or aluminum-doped silicon oxide. Transparent conductive oxide stack 510 can include any suitable number of additional barrier layers 500. According to one embodiment, a first silicon oxide can be deposited onto a silicon nitride, and the silicon nitride can be deposited onto a second silicon oxide; the second silicon oxide can be deposited onto a substrate. Alternatively, a first aluminum-doped silicon oxide can be deposited onto an aluminum-doped silicon nitride, and the aluminum-doped silicon nitride can be deposited onto a second aluminum-doped silicon oxide; the second aluminum-doped silicon oxide can be deposited onto a substrate. Transparent conductive oxide layer 320 can be deposited adjacent to second barrier layer 310. Transparent conductive oxide layer 320 can be deposited using any known deposition technique, including sputtering. Transparent conductive oxide layer 320 can include a cadmium stannate. Control layer 330 can be deposited adjacent to transparent conductive oxide layer 320 to enable proper transformation of transparent conductive oxide layer 320 (e.g., cadmium stannate). Control layer 330 can be deposited using any known deposition technique, including sputtering. Control layer 330 can include a tin oxide. Buffer layer 340 can be deposited adjacent to control layer 330 to facilitate proper deposition of semiconductor window layer 630 from FIG. 6. Buffer layer 340 can be deposited using any known deposition technique, including sputtering. Additional barrier layer(s) 500, first barrier layer 300, second barrier layer 310, transparent conductive oxide layer 320, control layer 330, and buffer layer 340 can form transparent conductive oxide stack 510. Transparent conductive oxide stack 510 from FIG. 5 can be annealed to form annealed transparent conductive oxide stack 610 from FIG. 6.

Annealed transparent conductive oxide stack 610 can be used to form photovoltaic device 60 from FIG. 6. Annealed transparent conductive oxide stack 610 can be deposited adjacent to a substrate 600. Annealed transparent conductive oxide stack 610 can be deposited using any known deposition technique, including sputtering. Substrate 600 can include a glass, for example, a soda-lime glass. Semiconductor bi-layer 620 can be deposited adjacent to annealed transparent conductive oxide stack 610. Semiconductor bi-layer 620 can include semiconductor window layer 630 and semiconductor absorber layer 640. Semiconductor window layer 630 can include a cadmium sulfide layer and can be deposited via any suitable deposition technique, including vapor transport deposition. Semiconductor absorber layer 640 can include a cadmium telluride layer and can be deposited adjacent to semiconductor window layer 630. Semiconductor absorber layer 640 can be deposited using any known deposition technique, including vapor transport deposition. A back contact 650 can be deposited adjacent to semiconductor bi-layer 620. Back contact 650 can be deposited adjacent to semiconductor absorber layer 640. A back support 650 can be deposited adjacent to back contact 650.

In one experiment, two sets of transparent conductive oxide stacks were formed consistent with two of the preferred embodiments. The first configuration consisted of: 75 nm tin(IV) oxide; 25 nm tin oxide; 250 nm cadmium stannate; 30 nm aluminum-doped silicon oxide; 30 nm aluminum-doped silicon nitride; and glass. The second configuration consisted of: 75 nm tin(IV) oxide; 25 nm tin oxide; 250 nm cadmium stannate; 100 nm aluminum-doped silicon nitride; and glass. Results indicated that stacks formed consistent with the first configuration were highly resistive, whereas, stacks formed consistent with the second configuration were not, underscoring the necessity for a post-sputtering annealing process to transform the stacks.

In a subsequent experiment, stacks formed according to the same configurations were annealed in a belt furnace in a low vacuum (nitrogen annealing would have achieved similar results). Nearly all of the stacks demonstrated desirable sheet resistance (less than 10 ohms/sq). Results also indicated that the stacks which included the barrier bi-layer of 30 nm aluminum-doped silicon nitride and 30 nm aluminum-doped silicon oxide performed better in reducing reflection loss and interference. In a similar experiment, the same stack configurations were annealed in a belt furnace in the presence of a nitrogen gas. Results indicated low sheet resistance (most between 5-9 ohms/sq), as well as desired absorption and transmission percentages. Results also indicated that the stacks which included the barrier bi-layer of 30 nm aluminum-doped silicon nitride and 30 nm aluminum-doped silicon oxide performed better in reducing reflection loss and interference.

In another experiment, stacks were formed according to the following configuration: 75 nm tin(IV) oxide; 25 nm tin oxide; 250 nm cadmium stannate; 30 nm aluminum-doped silicon oxide; 30 nm aluminum-doped silicon nitride; and glass. The stacks were annealed in a belt furnace with a low vacuum of about 0.01 Pa (10⁻⁴ Ton). Cadmium sulfide and cadmium telluride layers were deposited onto the stacks using vapor transport deposition. A device formed with the aforementioned stack configuration had smooth cadmium sulfide distribution, likely a result of proper application of the preceding buffer layer. Subsequent analysis indicated that the devices performed well, with average efficiency in the 10-12% range and fill factor in the 65-75% range.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic device, comprising:
a transparent conductive oxide layer adjacent to a substrate, the transparent conductive oxide layer comprising a cadmium stannate layer;
one or more barrier layers positioned between the substrate and the transparent conductive oxide layer, wherein each of the one or more barrier layers comprises a silicon oxide or a silicon nitride;
a tin oxide layer adjacent to the transparent conductive oxide layer;
a buffer layer adjacent to the tin oxide layer;
and a semiconductor bi-layer adjacent to the buffer layer, the semiconductor bi-layer comprising a semiconductor absorber layer adjacent to a semiconductor window layer.

2. The photovoltaic device of claim 1, wherein the one or more barrier layers comprises a silicon nitride or a silicon oxide.

3. The photovoltaic device of claim 1, wherein the one or more barrier layers comprises a silicon oxide layer adjacent to a silicon nitride layer.

4. The photovoltaic device of claim 1, wherein the one or more barrier layers comprises an aluminum-doped silicon oxide layer adjacent to an aluminum-doped silicon nitride layer.

5. The photovoltaic device of claim 1, wherein the one or more barrier layers comprises a first silicon oxide layer adjacent to a silicon nitride layer, wherein the silicon nitride layer is adjacent to a second silicon oxide layer.

6. The photovoltaic device of claim 1, wherein the one or more barrier layers comprises a first aluminum-doped silicon oxide layer adjacent to an aluminum-doped silicon nitride layer, wherein the aluminum-doped silicon nitride layer is adjacent to a second aluminum-doped silicon oxide layer.

7. The photovoltaic device of claim 1, wherein the tin oxide layer comprises a thickness of about 10 nm to about 100 nm.

8. A method for manufacturing a photovoltaic device, the method comprising:
depositing a transparent conductive oxide layer adjacent to one or more barrier layers, the transparent conductive oxide layer comprising a cadmium stannate layer, and each of the one or more barrier layers comprising a silicon oxide or a silicon nitride;
depositing a tin oxide layer adjacent to the transparent conductive oxide layer;
depositing a buffer layer adjacent to the tin oxide layer,
wherein the one or more barrier layers and the deposited transparent conductive oxide layer, tin oxide layer, and buffer layer form a transparent conductive oxide stack;
annealing the transparent conductive oxide stack;
depositing a semiconductor window layer adjacent to the transparent conductive oxide stack; and
depositing a semiconductor absorber layer adjacent to the semiconductor window layer.

9. The method of claim 8, further comprising depositing the one or more barrier layers adjacent to a substrate using a chemical vapor deposition process.

10. The method of claim 8, wherein depositing the one or more barrier layers comprises depositing a silicon nitride layer or a silicon oxide layer adjacent to the substrate.

11. The method of claim 8, wherein depositing the one or more barrier layers comprises:
depositing a silicon nitride layer adjacent to the substrate; and
depositing a silicon oxide layer adjacent to the silicon nitride layer.

12. The method of claim 8, wherein depositing the one or more barrier layers comprises:
depositing an aluminum-doped silicon nitride layer adjacent to the substrate; and
depositing an aluminum-doped silicon oxide layer adjacent to the aluminum-doped silicon nitride layer.

13. The method of claim 8, wherein depositing the one or more barrier layers comprises:
depositing a first silicon oxide layer adjacent to the substrate;
depositing a silicon nitride layer adjacent to the first silicon oxide layer; and
depositing a second silicon oxide layer adjacent to the silicon nitride layer.

14. The method of claim 8, wherein depositing the one or more barrier layers comprises:
depositing a first aluminum-doped silicon oxide layer adjacent to the substrate;
depositing an aluminum-doped silicon nitride layer adjacent to the first aluminum-doped silicon oxide layer; and
depositing a second aluminum-doped silicon oxide layer adjacent to the aluminum-doped silicon nitride layer.

15. The method of claim 8, wherein annealing the transparent conductive oxide stack comprises annealing in a nitrogen-containing atmosphere.

16. The method of claim 8, wherein depositing a tin oxide layer adjacent to the transparent conductive oxide layer comprises sputtering a tin oxide layer onto a cadmium stannate layer, the tin oxide layer comprising a thickness of about 10 nm to about 100 nm.

17. A multi-layered substrate, comprising:
a transparent conductive oxide layer adjacent to a substrate, the transparent conductive oxide layer comprising a cadmium stannate layer;
one or more barrier layers positioned between the substrate and the transparent conductive oxide layer, wherein each of the one or more barrier layers comprises a silicon oxide or a silicon nitride;
a tin oxide layer adjacent to the transparent conductive oxide layer; and
a buffer layer adjacent to the tin oxide layer.

18. A method for manufacturing a multi-layered substrate, the method comprising:
depositing one or more barrier layers adjacent to a first substrate;
depositing a transparent conductive oxide layer adjacent to the one or more barrier layers, the transparent conductive oxide layer comprising a cadmium stannate layer, and each of the one or more barrier layers comprising a silicon oxide or a silicon nitride;
depositing a tin oxide layer adjacent to the transparent conductive oxide layer;
depositing a buffer layer adjacent to the tin oxide layer,
wherein the first substrate, the deposited one or more barrier layers, transparent conductive oxide layer, tin oxide layer, and buffer layer form a transparent conductive oxide stack; and
annealing the transparent conductive oxide stack.
